(19) United States
(12) Patent Application Publication
(10) Pub. No.: US 2016/0087653 A1
(43) Pub. Date: Mar. 24, 2016

(54) Decoder With Targeted Symbol Flipping Recovery Of Miscorrected Codewords

(71) Applicant: LSI Corporation, San Jose, CA (US)

(72) Inventors: Shaohua Yang, San Jose, CA (US); Yu Chin Fabian Lim, San Jose, CA (US); Dan Liu, Shanghai (CN); Yoon L. Liow, Allentown, PA (US); Keklik Alptekin Bayam, San Jose, CA (US)

(21) Appl. No.: 14/444,916

(22) Filed: Jul. 28, 2014

(51) Int. Cl. H03M 13/37; H03M 13/11

(52) U.S. Cl. CPC H03M 13/3753; H03M 13/1128

(57) ABSTRACT

An apparatus for decoding data includes a decoder circuit operable to apply a decoding algorithm to a decoder input to yield a codeword, a convergence detection circuit operable to determine whether parity checks are satisfied by the decoder input and to identify unsatisfied parity checks in the decoder circuit, and a symbol flipping controller operable to change values of at least one symbol in the decoder input based on information about the unsatisfied parity checks. The decoder circuit is restarted to process the decoder input with the changed values. The information about the unsatisfied parity checks is obtained at each of a number of local decoding iterations in the decoder circuit.

### FIELD OF THE INVENTION

Various embodiments of the present inventions provide apparatuses and methods for targeted symbol flipping recovery of miscorrected codewords in a decoder.

### BACKGROUND

Various data transfer systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. In some cases, the data processing function receives data sets and applies a data decode algorithm to the data sets to recover an originally written data set. When data fails to converge in a decoder, an error recovery operation can be initiated to change decoder input values before again applying the data decode algorithm. However, such an error recovery operation increases latency and can produce multiple copies of the same results.

### SUMMARY

An apparatus for decoding data is disclosed including a decoder circuit operable to apply a decoding algorithm to a decoder input to yield a codeword, a convergence detection circuit operable to determine whether parity checks are satisfied by the decoder input and to identify unsatisfied parity checks in the decoder circuit, and a symbol flipping controller operable to change values of at least one symbol in the decoder input based on information about the unsatisfied parity checks. The decoder circuit is restarted to process the decoder input with the changed values. The information about the unsatisfied parity checks is obtained at each of a number of local decoding iterations in the decoder circuit.

This summary provides only a general outline of some embodiments of the invention. Additional embodiments are disclosed in the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals may be used throughout several drawings to refer to similar components.

FIG. 1 depicts a block diagram of a data processing system with a decoder with targeted symbol flipping recovery of miscorrected codewords in accordance with some embodiments of the present invention;

FIG. 2 depicts a block diagram of a low density parity check decoder with targeted symbol flipping recovery of miscorrected codewords in accordance with some embodiments of the present invention;

FIG. 3 depicts a diagram of a codeword memory and hash calculator and comparator in a decoder in accordance with some embodiments of the present invention;

FIG. 4 depicts a codeword hash calculation in accordance with some embodiments of the present invention;

FIG. 5 depicts a diagram of an unsatisfied parity check count comparator that can be used to initiate a targeted symbol flipping operation during and between local decoding iterations in a decoder in accordance with some embodiments of the present invention;

FIG. 6 depicts a flow diagram showing a method for initiating a targeted symbol flipping operation in a decoder based on supplementary unsatisfied parity check information and for preventing duplicate codewords in accordance with various embodiments of the present invention;

FIG. 7 depicts a storage system including a decoder with targeted symbol flipping recovery of miscorrected codewords using hashing and supplementary unsatisfied parity check information in accordance with some embodiments of the present invention; and

FIG. 8 depicts a wireless communication system including a decoder with targeted symbol flipping recovery of miscorrected codewords using hashing and supplementary unsatisfied parity check information in accordance with some embodiments of the present invention.

### DETAILED DESCRIPTION OF THE INVENTION

A decoder with targeted symbol flipping recovery of miscorrected codewords is disclosed herein which uses supplementary unsatisfied parity check information to initiate early targeted symbol flipping operations and which uses hashing to prevent duplicate output codewords. The targeted symbol flipping recovery of miscorrected codewords can be applied in any suitable data decoder, such as, but not limited to, a low density parity check (LDPC) decoder. Decoder technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as dynamic random-access memory, negated-AND flash, negated-OR flash, other non-volatile memories and solid state drives.

A decoder decodes blocks of data, such as a data sector read from a magnetic hard disk drive, generating codewords and yielding hard decisions for the codewords as a decoded output when parity checks are satisfied for the codewords. Targeted symbol flipping is initiated when normal decoding fails, for example when the data in the decoder fails to converge on values that satisfy all parity checks or other error correction code constraints. Targeted symbol flipping is also initiated when the data converges on values that satisfy all parity checks but which are not fully correct, a condition that can be detected using cyclic redundancy checks (CRCs) or other additional tests.

During targeted symbol flipping, the input values to the decoder for selected bits or symbols are changed and decoding is repeated in an attempt to cause the decoder to converge. The term “symbol flipping” is used herein to refer to changing the values of symbols during a decoding operation in an attempt to cause the codewords to converge on values which satisfy parity checks. The symbols may each include one or more bits. In a non-binary decoder, a symbol may be flipped by changing the hard decision and/or log-likelihood ratio (LLR) input value to a different element of the Galois Field associated with the decoder. For example, in a GF(4) decoder, the symbol can be flipped by adding 1, 2 or 3 to the hard decision. The symbol flipping can be performed in any manner suitable to the particular decoder and the format of its input. For example, the input to the decoder can consist of a hard decision identifying one of the Galois Field elements as the most likely real value along with a log likelihood ratio value for each of the other Galois Field elements, indicating the likelihood that the real value corresponds to each of the other Galois Field elements. In this case, the symbol can be flipped by selecting another of the Galois Field elements as the hard decision.

In some embodiments, the codeword generated by the decoder corresponds to an entire data sector of a storage device. In some embodiments, the codeword is subdivided into portions referred to as component codewords. For example, in some embodiments the codeword is divided into four component codewords which are independently decoded, with convergence being checked in the decoder for a component codeword at the end of a local decoding iteration and/or at intermediate stages during a local decoding iteration based on supplementary information about unsatisfied parity checks, also referred to herein as intermediate information about unsatisfied parity checks.

The supplementary information about unsatisfied parity checks can include a count and list of unsatisfied parity checks generated at the end of each local decoding iteration, and in some embodiments, generated during local decoding iterations as the list of unsatisfied parity checks is updated while the local decoding iteration is performed. Furthermore, after a local decoding iteration with a larger number of unsatisfied parity checks than can typically be resolved with targeted symbol flipping, rather than simply terminating the decoding operation or attempting a different recovery option, additional local decoding iterations can be performed to determine whether the number of unsatisfied parity checks continues to decline. Where the number of unsatisfied parity checks continues to decline with additional local decoding iterations, the decoding process is continued and when the number of unsatisfied parity checks falls below a threshold, the local decoding iterations are stopped and a targeted symbol flipping operation is initiated. Intermediate information about unsatisfied parity checks helps miscorrection recovery by providing information from each local iteration, allowing the decoder to arrive at a state in which targeted symbol flipping can be successful, rather than simply giving up when an iteration results in an overwhelmingly large number of unsatisfied checks.

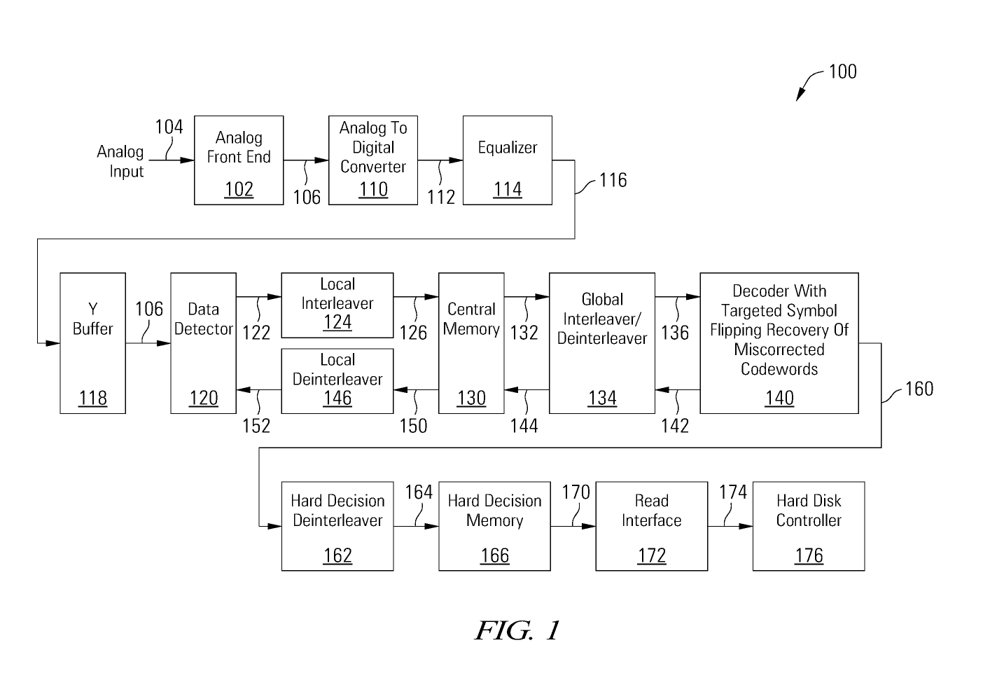

Turning now to FIG. 1, a data processing system 100 is depicted including a decoder 140 with targeted symbol flipping recovery of miscorrected codewords in accordance with some embodiments of the present invention. In particular, data processing system 100 may comprise a read channel for a magnetic storage device such as a hard disk drive. Data processing system 100 includes an analog front end circuit 102 that receives an analog signal 104. Analog front end circuit 102 processes analog signal 104 and provides a processed analog signal 106 to an analog to digital converter circuit 110. Analog front end circuit 102 may include, but is not limited to, an analog filter and an amplifier circuit as are known in the art. Based upon the disclosure provided herein, one of ordinary skill in the art will recognize a variety of circuitry that may be included as part of analog front end circuit 102. In some cases, analog signal 104 is derived from a read/write head assembly that is disposed in relation to a storage medium. In other cases, analog signal 104 is derived from a receiver circuit that is operable to receive a signal from a transmission medium. The transmission medium may be wired or wireless. Based upon the disclosure provided herein, one of ordinary skill in the art will recognize a variety of sources from which analog input 104 may be derived.

Analog to digital converter circuit 110 converts processed analog signal 106 into a corresponding series of digital samples 112. Analog to digital converter circuit 110 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 112 are provided to an equalizer circuit 114. Equalizer circuit 114 applies an equalization algorithm to digital samples 112 to yield an equalized output 116. In some embodiments of the present inventions, equalizer circuit 114 is a digital finite impulse response (DFIR) filter circuit as are known in the art. Equalized output 116 is stored in a memory or Y buffer 118. In some cases, equalized output 116 is received directly from a storage device in, for example, a solid state storage system. In such cases, analog front end circuit 102, analog to digital converter circuit 110 and equalizer circuit 114 can be eliminated where the data is received as a digital data input.

Equalized data 106 is provided to a data detector circuit 120, which is operable to apply a data detection algorithm to a received codeword or data set, and in some cases data detector circuit 120 can process two or more codewords in parallel. In some embodiments of the present invention, data detector circuit 120 is a Viterbi algorithm data detector circuit as is known in the art. In other embodiments of the present inventions, data detector circuit 120 is a maximum a posteriori data detector circuit as is known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present inventions. Data detector circuit 120 is started based upon availability of a data set from Y buffer 118 or from a central memory circuit 130.

Upon completion, data detector circuit 120 provides detector output 122, or soft data. As used herein, the phrase “soft data” is used in its broadest sense to mean reliability data with each instance of the reliability data indicating a likelihood that a corresponding bit position or group of bit positions has been correctly detected. In some embodiments of the present inventions, the soft data or reliability data is log likelihood ratio data as is known in the art. Detected output 122 is provided to a local interleaver circuit 124. Local interleaver circuit 124 is operable to shuffle sub-portions (i.e., local chunks) of the data set included as detected output 122 and provides an interleaved codeword 126 that is stored to central memory circuit 130. Interleaver circuit 124 may be any circuit known in the art that is capable of shuffling data sets to yield a re-arranged data set. Interleaved codeword 126 is stored to central memory circuit 130. The interleaved codeword 126 is accessed from central memory circuit 130 as a stored codeword 132 and globally interleaved by a global interleaver/de-interleaver circuit 134. Global interleaver/De-interleaver circuit 134 may be any circuit known in the art that is capable of globally rearranging codewords. Global interleaver/De-interleaver circuit 134 provides a decoder input 136 to a low density parity check decoder 140 with targeted symbol flipping recovery of miscorrected codewords. Based upon the disclosure provided herein, one of ordinary skill in the art will recognize other decode algorithms that may be used in relation to different embodiments of the present invention, in association with the targeted symbol flipping recovery of miscorrected codewords disclosed herein. The decoder 140 applies a data decode algorithm to decoder input 136 in a variable number of local iterations.

Where the decoder 140 fails to converge (i.e., fails to yield the originally written data set) and a number of local iterations through LDPC decoder 140 exceeds a threshold, the resulting decoded output can be provided as a decoded output 142 back to central memory circuit 130 where it is stored awaiting another global iteration through data detector circuit 120 and decoder 140. Multiple sectors may be processed simultaneously in the data processing system 100, with additional sectors being admitted to the data detector 120 as other sectors converge in the decoder 140 and are output and cleared from the Y buffer 118 and central memory circuit 130.

Prior to storage of decoded output 142 to central memory circuit 130, decoded output 142 is globally de-interleaved to yield a globally de-interleaved output 144 that is stored to central memory circuit 130. The global de-interleaving reverses the global interleaving earlier applied to stored codeword 132 to yield decoder input 136. Once data detector circuit 120 is available, a previously stored de-interleaved output 144 is accessed from central memory circuit 130 and locally de-interleaved by a de-interleaver circuit 146. De-interleaver circuit 146 re-arranges stored decoder output 150 to reverse the shuffling originally performed by interleaver circuit 124. A resulting de-interleaved output 152 is provided to data detector circuit 120 where it is used to guide subsequent detection of a corresponding data set received as equalized output 116.

Alternatively, where the decoded output converges (i.e., yields the originally written data set) in the decoder 140, the resulting decoded output is provided as an output codeword 160 to a hard decision deinterleaver 162, which rearranges the data to reverse both the global and local interleaving applied to the data to yield a de-interleaved output 164. De-interleaved output 164 is stored in a hard decision memory 166 and is then provided to a read interface 172, which can perform additional error checking such as cyclic redundancy checks (CRC) on the de-interleaved output 164. Data 174 can then be forwarded to a hard disk controller 176 or other destination, either automatically or as instructed by the decoder 140.

When the decoder input 136 fails to converge in the decoder 140, or converges on incorrect codewords, one or more symbols at a time can be flipped in the decoder 140, based on a list of check nodes in the decoder 140 which fail parity checks. Supplemental or intermediate information about the unsatisfied parity checks can be used to trigger targeted symbol flipping in the decoder 140, in some cases even if the number of unsatisfied parity checks is initially larger than can normally be resolved with targeted symbol flipping, and in some cases by monitoring information about unsatisfied parity checks that is updated as while decoding is ongoing, during a local decoding iteration.

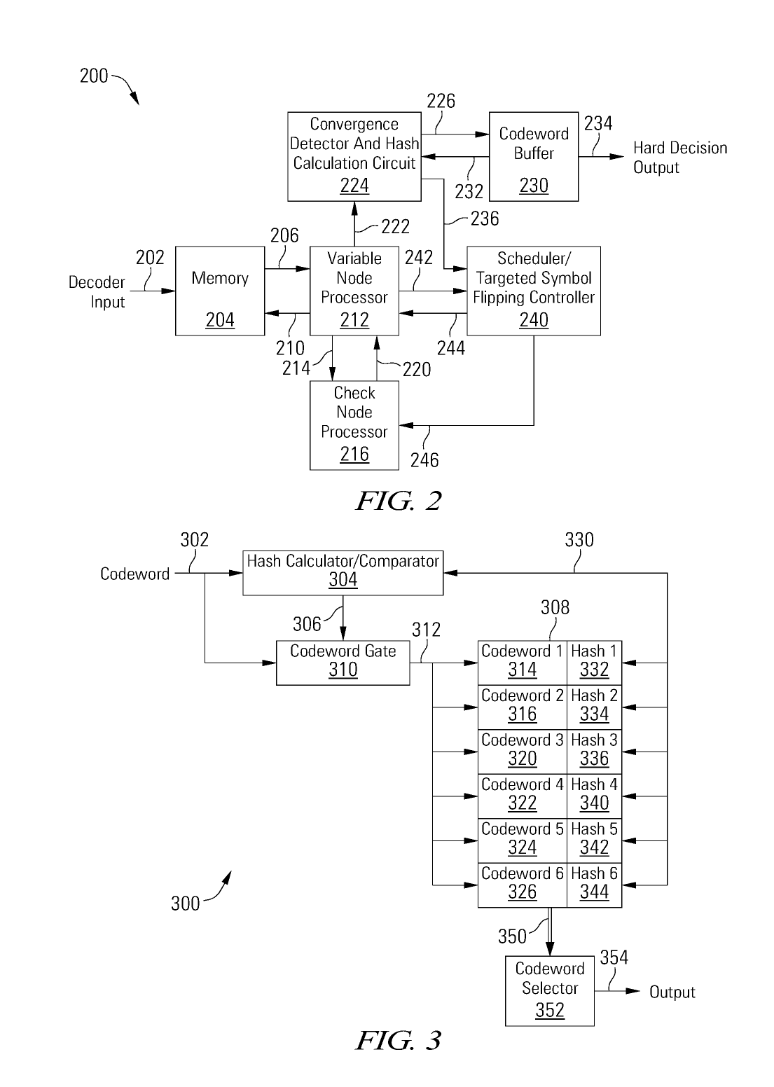

Turning to FIG. 2, a low density parity check decoder 200 with targeted symbol flipping recovery of miscorrected codewords is depicted in accordance with some embodiments of the present invention. A decoder input 202 is stored in memory 204, representing the likelihoods or perceived values of each symbol in the data being decoded. A variable node processor 212 reads the perceived values 206 and stores updated values 210, and exchanges variable node to check node messages 214 and check node to variable node messages 220 with a check node processor 216 in an iterative decoding process.

A convergence detector and hash calculation circuit 224 determines whether data has converged in the decoder 200 by determining whether the syndrome s=cH^{T} is all zero. A low density parity check code is defined by a sparse parity check matrix H of size m×n, where m<n. A codeword c of length n satisfies all the m parity check equations defined by H, i.e., cH^{T}=0, where 0 is a zero vector. The syndrome is a vector of length m, with each bit corresponding to a parity check in the parity check matrix or H matrix. A zero bit in a syndrome means the check is satisfied, while a non-zero bit in the syndrome is an unsatisfied check (USC). By definition, a codeword c, defined by the hard decisions 222 from the variable node processor 212, has syndrome s=0. A non-codeword has a non-zero syndrome. The syndrome is calculated in the convergence detector and hash calculation circuit 224 as the dot product of the codeword c and the parity check matrix H.

The convergence detector and hash calculation circuit 224 also calculates a hash value for the codeword c or for component codewords that combine to form codeword c. As codewords are generated in the decoder 200, they can be stored in codeword buffer 230, forming a pool or candidate codewords, some of which may be miscorrected codewords that satisfy the parity checks but which are not identical to the original data. The convergence detector and hash calculation circuit 224 includes a comparator that compares the newly calculated hash value for the current codeword or component codeword with previously calculated hash values 232 corresponding to codewords or component codewords stored in a codeword buffer 230, generated by previous decoding iterations for the same data sector. If the newly calculated hash value for the current codeword or component codeword is different from the previously calculated hash values 232, it is assumed that the current codeword or component codeword is unique and not identical to any stored in codeword buffer 230, and the codeword or component codeword and its hash value 226 are stored in codeword buffer 230. After storing a number of codewords in codeword buffer 230, one of them is selected as the output codeword and the corresponding hard decisions 234 are output. The selection of the output codeword can be performed in any suitable manner, for example using a cyclic redundancy check to identify the correct codeword. The selection of the output codeword can be triggered in one more manners, such as when the codeword buffer 230 is full, or after a particular number of local and/or global decoding iterations has been performed, or when a read interface has requested that another data sector be read and the data processing system is needed for other tasks, etc. The convergence detector and hash calculation circuit 224 can be implemented as independent circuits or as a combined circuit containing syndrome and hash calculation circuits.

A scheduler and targeted symbol flipping controller 240 controls both normal decoding and retry operations in the decoder 200. The scheduler and targeted symbol flipping controller 240 provides decoding instructions 244, 246 to the variable node processor and check node processor 216 about circulants to be processed, etc. During a symbol flipping operation, the scheduler and targeted symbol flipping controller 240 also includes symbols flipping information in instructions 244, and receives unsatisfied check information 236 and symbol values 242 enabling it to determine which symbols to flip and which values can be tried.

Turning to FIG. 3, a codeword memory with hash calculator and comparator 300 that can be used in a decoder to store codeword candidates in accordance with some embodiments of the present invention. As a codeword 302 is generated during a decoding and/or retry operation in a decoder (e.g., 200), a hash calculator and comparator circuit 304 calculates a hash value for the codeword 302 using any suitable technique, such as, but not limited to, an XOR operation of the bits in the codeword 302. In some embodiments, the hash calculator and comparator circuit 304 computes the hash value for the uniqueness check based on the accumulated syndrome of the processed data set. The hash calculator and comparator circuit 304 compares the newly calculated hash value with hash values 330 stored in memory 308 for codewords stored in memory 308 that were generated previously in the decoding or retry operation. If the newly calculated hash value is different than any of the hash values 330 stored in memory 308, it can be assumed that the codeword 302 is unique and not already stored in memory 308. A codeword gate 310 allows the codeword 302 to be stored in memory 308 based on the indication 306 from the hash calculator and comparator circuit 304 that the hash value for the codeword 302 is unique. For example, assume that three different codewords were previously generated for a data sector and stored in codeword slots 314, 316, 320 of memory 308, with their hash values stored in hash slots 332, 334, 336 of memory 308, and assuming that memory 308 can contain 6 codewords. Codeword slots 322, 324, 326 and corresponding hash slots 340, 342, 344 remain available for use. When a newly generated codeword 302 is available, hash calculator and comparator circuit 304 calculates the hash value for codeword 302 and compares it with the hashes stored in hash slots 332, 334, 336. If the new hash value matches any of the previous hashes, codeword 302 is a duplicate of one of those stored in codeword slots 314, 316, 320 and is discarded. If, on the other hand, the new hash value does not match any of the previous hashes, codeword 302 is stored in an available slot (e.g., 322) in memory 308. Thus, memory 308 is prevented from filling up with duplicate codewords that might be generated during the targeted symbol flipping operation.

In some embodiments, the contents of the codeword memory 308 are updated each time a component codeword is available, or a portion of a codeword, and in these cases, the hash calculation, storage and comparison can be done on a component codeword basis.

Completion of a symbol flipping operation can be based on any suitable conditions, such as, but not limited to, the codeword memory 308 becoming full, or a limit on processing time for a sector being reached, or a read request for other data requiring the decoder to move on, etc. Any suitable technique can be used to select one of the codewords 350 stored in codeword memory being selected as output 354 by a codeword selector 352. For example, in some embodiments the codeword selector 352 applies cyclic redundancy checks to candidate codewords in codeword memory 308 to select the correct codeword.

Depending on the complexity of the hash algorithm applied by hash calculator and comparison circuit 304, it is possible that some duplication of codewords may remain. However, the goal of avoiding duplicate codewords can be balanced against the need for efficient hash calculations and for compact and low power hardware. A simpler hash algorithm can be faster and require less power and complex circuitry, at the greater risk of duplicate codewords. A more complex hash algorithm can provide better protection against duplicate codewords, at the possible costs of higher memory requirements to store hash values, greater latency in calculating hash values and more complex hash calculation circuits.

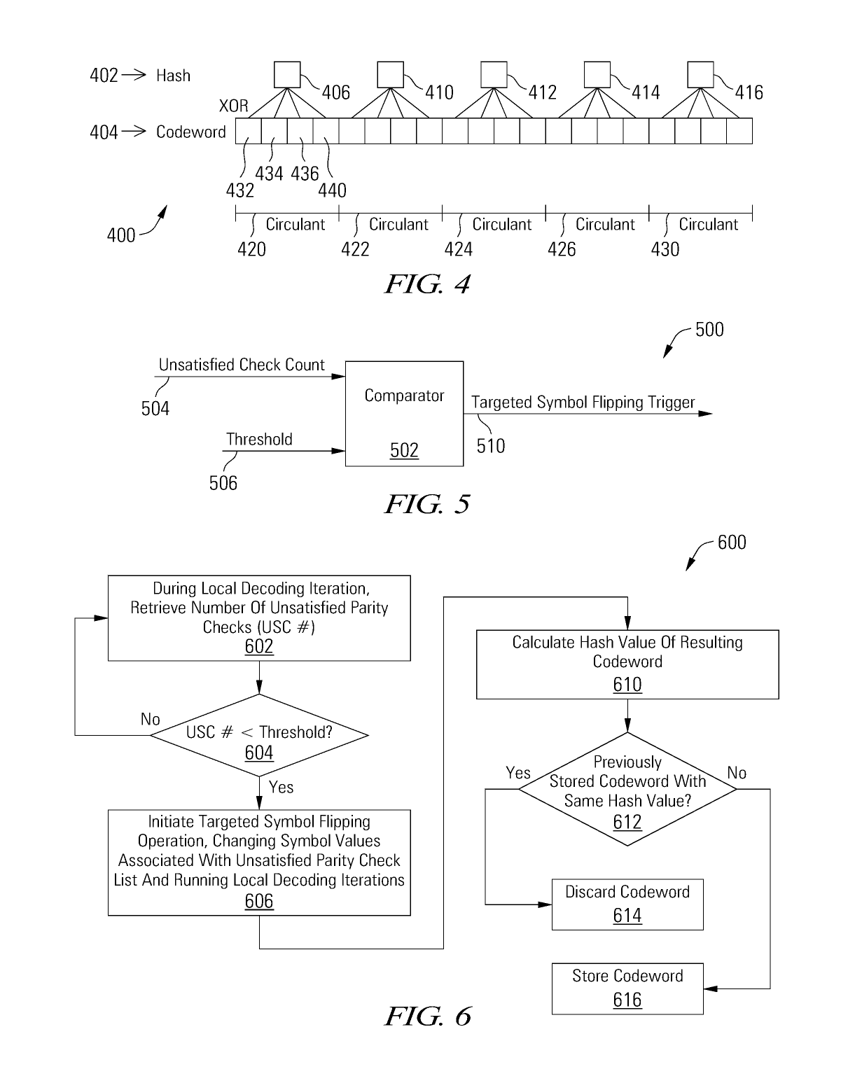

Turning to FIG. 4, a diagram 400 depicts an example hash calculation in accordance with some embodiments of the invention. In this embodiment, all bits in the same circulant 420, 422, 424, 426, 430 are XORed together to yield hash bits 406, 410, 412, 414, 416. For example, bits 432, 434, 436, 440 of circulant 420 are XORed to yield hash bit 406. (The diagram 400 is simplified, not showing all bits of circulants for a codeword 404 or all resulting bits in the hash 402.) Again, the codeword can be divided in any convenient manner with sub-portions updated when they are available from the decoder, calculating hash values circulant by circulant in a quasi-cyclic decoder that processes in circulant-wise fashion. In such a decoder, with a code having 108 circulants, the hash will be a 108 bit vector, one bit per circulant.

Targeted symbol flipping can be initiated at various times during decoding when the number of unsatisfied parity checks falls below a threshold, and not just at the end of the first local decoding iteration. Turning to FIG. 5, a 500 diagram depicts an unsatisfied parity check count comparator 502 that can be used to initiate a targeted symbol flipping operation during and between local decoding iterations in a decoder in accordance with some embodiments of the present invention. The unsatisfied parity check count 504 is compared with a threshold 506 by the comparator 502, and a trigger signal 510 is asserted to initiate targeted symbol flipping when the number of unsatisfied parity checks is below the threshold 506. The threshold 506 is set at a level low enough that targeted symbol flipping can be expected to overcome the remaining unsatisfied parity checks to help data converge. When the number of unsatisfied parity checks is above the threshold, targeted symbol flipping is generally not effective or efficient enough.

However, in some embodiments, when the number of unsatisfied parity checks 504 is greater than the threshold 506, for example at the end of the first local decoding iteration of a particular global decoding iteration, local decoding iterations can be continued while the number of unsatisfied parity checks 504 decreases, in the hope that it will fall below the threshold 506 and targeted symbol flipping can be initiated. For example, Table 1 below gives the number of unsatisfied parity checks for two component codewords as they are processed in parallel in a low density parity check decoder:

TABLE 1

| Local Iteration | USC Count CCW0 | USC Count CCW1 |
|---|---|---|
| 0 | 146 | 180 |
| 1 | 51 | 58 |
| 2 | 16 | 35 |
| 3 | 7 | 16 |
| 4 | 2 | 0 |
| 5 | 0 | |

At the end of the first local decoding iteration, the number of unsatisfied parity checks for a first component codeword CCW0 is 146, and for a second component codeword CCW1 is 180. If at most 7 unsatisfied parity checks can be expected to be corrected by targeted symbol flipping in an acceptable manner, the threshold is set at 7 (for a less than or equal to comparison) or 8 (for a less than comparison). Notably, although the number of unsatisfied parity checks is unacceptably high for targeted symbol flipping initially, additional local decoding iterations can be performed until the number of unsatisfied parity checks falls. In this case, targeted symbol flipping can be initiated for the first component codeword CCW0 after local decoding iteration 3, when the number of unsatisfied parity checks has fallen to 7. In some embodiments which process multiple circulants in parallel, the number of unsatisfied parity checks is examined for circulant pairs that are being processed in parallel, and targeted symbol flipping is initiated at the first convergence check for the circulant pair that satisfies the threshold.

In some embodiments, the targeted symbol flipping is performed on the initial decoder input. In some other embodiments, the targeted symbol flipping is performed on the later results of one or more local decoding iterations, effectively rolling back the state of the data to a point where targeted symbol flipping can be productive.

Turning to FIG. 6, a flow diagram 600 depicts an operation for initiating a targeted symbol flipping operation in a decoder based on supplementary unsatisfied parity check information and for preventing duplicate codewords in accordance with various embodiments of the present invention. Following flow diagram 600, the number of unsatisfied parity checks is retrieved during a local decoding iteration. (Block 602) This can be performed as convergence checks are performed to update the list of unsatisfied parity checks in the middle of a local decoding iteration or at the end of the local decoding iteration. A determination is made as to whether the number of unsatisfied parity checks is less than a threshold. (Block 604) If the number of unsatisfied parity checks is not less than the threshold, local decoding iterations can be continued in an attempt to reduce the number of unsatisfied parity checks. If the number of unsatisfied parity checks is less than the threshold, a targeted symbol flipping operation is initiated, thereby changing symbol values associated with unsatisfied parity check list and running local decoding iterations. (Block 606) As a resulting codeword is generated, the hash value of the codeword is calculated. (Block 610) The hash value can be calculated for an entire codeword in one operation, or can be calculated piecewise, for example by component codeword, with the resulting hashes either combined for the overall codeword or kept separate. A determination is made as to whether a previously stored codeword exists with the same hash value. (Block 612) If so, the new codeword is a duplicate and is discarded. (Block 614) If not, the new codeword is assumed to be unique and is stored. (Block 616)

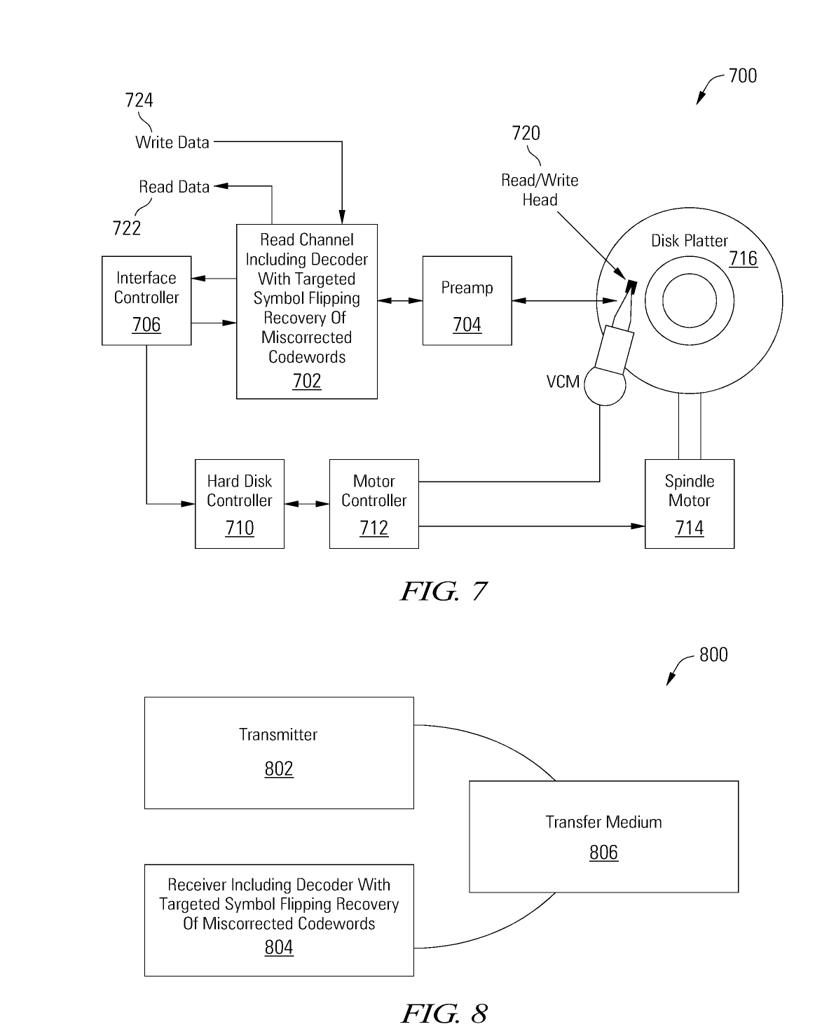

Although the targeted symbol flipping recovery of miscorrected codewords disclosed herein is not limited to any particular application, several examples of applications are presented in FIGS. 7 and 8 that benefit from embodiments of the present invention. Turning to FIG. 7, a storage system 700 is illustrated as an example application of targeted symbol flipping recovery of miscorrected codewords in accordance with some embodiments of the present inventions. The storage system 700 includes a read channel circuit 702 with a decoder with targeted symbol flipping recovery of miscorrected codewords in accordance with some embodiments of the present invention. Storage system 700 may be, for example, a hard disk drive. Storage system 700 also includes a preamplifier 704, an interface controller 706, a hard disk controller 710, a motor controller 712, a spindle motor 714, a disk platter 716, and a read/write head assembly 720. Interface controller 706 controls addressing and timing of data to/from disk platter 716. The data on disk platter 716 consists of groups of magnetic signals that may be detected by read/write head assembly 720 when the assembly is properly positioned over disk platter 716. In one embodiment, disk platter 716 includes magnetic signals recorded in accordance with either a longitudinal or a perpendicular recording scheme.

In a typical read operation, read/write head assembly 720 is accurately positioned by motor controller 712 over a desired data track on disk platter 716. Motor controller 712 both positions read/write head assembly 720 in relation to disk platter 716 and drives spindle motor 714 by moving read/write head assembly 720 to the proper data track on disk platter 716 under the direction of hard disk controller 710. Spindle motor 714 spins disk platter 716 at a determined spin rate (RPMs). Once read/write head assembly 720 is positioned adjacent the proper data track, magnetic signals representing data on disk platter 716 are sensed by read/write head assembly 720 as disk platter 716 is rotated by spindle motor 714. The sensed magnetic signals are provided as a continuous, minute analog signal representative of the magnetic data on disk platter 716. This minute analog signal is transferred from read/write head assembly 720 to read channel circuit 702 via preamplifier 704. Preamplifier 704 is operable to amplify the minute analog signals accessed from disk platter 716. In turn, read channel circuit 702 decodes and digitizes the received analog signal to recreate the information originally written to disk platter 716. This data is provided as read data 722 to a receiving circuit. As part of decoding the received information, read channel circuit 702 applies targeted symbol flipping recovery of miscorrected codewords when decoding fails to converge normally. Such targeted symbol flipping recovery of miscorrected codewords can be implemented consistent with that disclosed above in relation to FIGS. 2-6. A write operation is substantially the opposite of the preceding read operation with write data 724 being provided to read channel circuit 702. This data is then encoded and written to disk platter 716.

It should be noted that storage system 700 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 700, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

Turning to FIG. 8, a wireless communication system 800 or data transmission device including a receiver 804 with targeted symbol flipping recovery of miscorrected codewords is shown in accordance with some embodiments of the present inventions. Communication system 800 includes a transmitter 802 that is operable to transmit encoded information via a transfer medium 806 as is known in the art. The encoded data is received from transfer medium 806 by receiver 804. Receiver 804 incorporates a decoder with targeted symbol flipping recovery of miscorrected codewords. Such targeted symbol flipping recovery of miscorrected codewords can be implemented consistent with that disclosed above in relation to FIGS. 2-6.

It should be noted that the various blocks discussed in the above application may be implemented in integrated circuits along with other functionality. Such integrated circuits may include all of the functions of a given block, system or circuit, or only a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel apparatuses and methods for low density parity check decoding with targeted symbol flipping recovery of miscorrected codewords. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus for decoding data comprising:
a decoder circuit operable to apply a decoding algorithm to a decoder input to yield a codeword;
a convergence detection circuit operable to determine whether parity checks are satisfied by the decoder input and to identify unsatisfied parity checks in the decoder circuit; and
a symbol flipping controller operable to change values of at least one symbol in the decoder input based on information about the unsatisfied parity checks, wherein the decoder circuit is restarted to process the decoder input with the changed values, and wherein the information about the unsatisfied parity checks is obtained at each of a plurality of local decoding iterations in the decoder circuit.

2. The apparatus of claim 1, wherein the symbol flipping controller is operable to receive the information about the unsatisfied parity checks from the convergence detection circuit during a local decoding iteration while that local decoding iteration is ongoing in the decoder circuit.

3. The apparatus of claim 1, wherein the symbol flipping controller is operable to initiate a targeted symbol flipping operation in the decoder circuit when a count of the unsatisfied parity checks falls below a threshold.

4. The apparatus of claim 3, wherein the symbol flipping controller is operable to initiate the targeted symbol flipping operation after a first of the local decoding iterations at which the count of the unsatisfied parity checks falls below the threshold.

5. The apparatus of claim 3, wherein the symbol flipping controller is operable to initiate the targeted symbol flipping operation after the count of the unsatisfied parity checks for a component codeword corresponding with a portion of the decoder input falls below the threshold.

6. The apparatus of claim 1, wherein the symbol flipping controller is operable to monitor a count of the unsatisfied parity checks identified by the convergence detection circuit over a number of the local decoding iterations and to initiate a targeted symbol flipping operation in the decoder circuit when the count of the unsatisfied parity checks falls below a threshold.

7. The apparatus of claim 6, wherein the local decoding iterations are continued beyond a limit on a number of local decoding iterations when the count of the unsatisfied parity checks continues to fall.

8. The apparatus of claim 1, further comprising a hash calculation circuit operable to calculate and compare hashes for each codeword produced by the decoder circuit for versions of the decoder input to prevent storing duplicate codewords.

9. The apparatus of 8, wherein the hashes are calculated based on an accumulated syndrome for the codeword.

10. The apparatus of claim 8, wherein at least some of the versions of the decoder input comprise the decoder input with at least one flipped symbol.

11. The apparatus of claim 1, wherein the decoder circuit comprises a low density parity check decoder circuit.

12. The apparatus of claim 1, wherein the decoder circuit comprises a quasi-circulant low density parity check decoder circuit.

13. The apparatus of claim 1, wherein the decoder circuit, the convergence detection circuit and the symbol flipping controller comprise an integrated circuit.

14. The apparatus of claim 1, wherein the decoder circuit, the convergence detection circuit and the symbol flipping controller are incorporated in a storage device.

15. A method for data decoding with symbol flipping, comprising:
performing a plurality of local decoding iterations in a low density parity check decoder;
generating a list of unsatisfied parity checks at least after each of the local decoding iterations;
comparing a count of the unsatisfied parity checks with a threshold at least after each of the local decoding iterations; and
when the count of the unsatisfied parity checks is less than the threshold, initiating a symbol flipping retry operation in the low density parity check decoder.

16. The method of claim 15, wherein at least some of the plurality of local decoding iterations are performed after a maximum number of local decoding iterations has been performed and when the count of the unsatisfied parity checks is decreasing as the decoding continues.

17. The method of claim 15, wherein the generating and the comparing are performed partway through at least one of the plurality of local decoding iterations.

18. The method of claim 15, further comprising calculating a hash value for each of a plurality of codewords generated by the low density parity check decoder for a same decoder input based on the symbol flipping retry operation.

19. The method of claim 15, further comprising comparing the hash value for each of a plurality of codewords and storing only unique ones of the plurality of codewords in an output memory.

20. An apparatus for decoding data comprising:
a low density parity check decoder circuit comprising a decoder input, a variable node processor connected to the decoder input, a check node processor connected to the variable node processor, a codeword memory connected to the variable node processor, and a hard decision output connected to the check node processor;
a convergence detection circuit connected to the variable node processor, comprising an unsatisfied parity check count output;
a symbol flipping controller comprising a comparator connected to the unsatisfied parity check count output and to a threshold signal;
a hash calculation circuit connected to the variable node processor; and
a hash comparison circuit connected to the hash calculation circuit and to the codeword memory.
